(19) United States
(12) Patent Application Publication
(10) Pub. No.: US 2005/0168231 A1
(43) Pub. Date: Aug. 4, 2005

(54) Methods and structures for electronic probing arrays

(76) Inventor: Young-Gon Kim, Cupertino, CA (US)

Correspondence Address: LERNER DAVID, LITENBERG, KRUMHOLZ & MENTLIK, 600 SOUTH AVENUE WEST, WESTFIELD, NJ, 07090, US

(21) Appl. No.: 11/019,600

(22) Filed: Dec. 22, 2004

Related U.S. Application Data
(60) Provisional application No. 60/532,706, filed on Dec. 24, 2003.

(51) Int. Cl. G01R 31/02

(52) U.S. Cl. 324/754

(57) ABSTRACT

A probe for testing semiconductor chips includes a plurality of probe contacts providing z-direction compliancy. The probe contacts include a blind opening surrounded by a lateral sidewall for receiving an aligned chip contact. The chip contacts are manipulated with a downward vertical force and along a horizontal path for engagement with various portions of the probe contact within the blind opening. The alignment may be actively monitored for determining minimum contact resistance during the probing process.

### CROSS REFERENCES TO RELATED APPLICATIONS

This application claims the benefit of the filing date of U.S. Provisional Patent Application No. 60/532,706 filed on Dec. 24, 2003, the disclosure of which is hereby incorporated herein by reference.

### BACKGROUND OF THE INVENTION

Semiconductor chips are typically manufactured en masse in so called wafers. Each wafer is made of a semiconductor material and typically is four to twelve inches in diameter. Each wafer typically contains a plurality of identical chips each connected and adjacent one another, but separated by portions of the wafer called scribe lines. The scribe lines do not contain devices which are required in the finished chips. Generally, the individual chips are separated (or “diced”) from one another for packaging and/or electrical connection to other chips. Prior to the further processing and connection, however, the chips are desirably tested in order to determine which chips are defective so that further expense in processing does not occur on the defective chips. The testing is typically called “probing.” This testing may be accomplished by testing a single chip or multiple chips in defined rows on the wafer, and then repeating the testing operation with other chips or rows. Alternatively, the chips may be separated from one another first and then tested individually. Typically, probe contacts are abutted against (and preferably gently scrubbed or scraped against) respective chip contacts so that the chip circuitry may be tested.

When probing chips or wafers, it has been important to have a planar set of probe contacts so that each probe contact can make simultaneous electrical contact to a respective chip contact. It has also been important to have the contacts on the wafer coplanar. Typically, if the tips of the probe contacts do not lie in approximately the same plane, or if some of the contacts on the wafer are out of plane, more force must be exerted on the back of the probe in an effort to engage all of the probe contacts with the chip contacts. This typically leads to non-uniform forces between the tips of the probe contacts and the wafer contacts. If too much force is placed on any one probe contact, there is a potential to harm the chip contacts. Planarity and a balanced probe contact force is also important in order to have approximately the same ohmic resistance across all of the probe contacts so that the electrical signals have approximately the same level of integrity. Maintaining similar ohmic probe to chip contact resistance is especially important for accurate testing of chips that are designed to be run at high speeds. For these high-speed chips, it is also important to control the impedance of the probe tester (resistance, capacitance and inductance) as a whole to maintain the integrity of the electrical signals.

As previously discussed, it has been generally desirable to have a planar set of chip contacts so that each chip contact can make simultaneous electrical contact to a respective probe contact. The typical failure mode of such a probe card is the absence of the probe contacts uniformly engaging the end surfaces of the chip contacts. These circumstances result in a number of inherent problems during the probing process as described hereinabove. It is therefore desirable to provide a probe which can accommodate the lack of planarity in the contacts of a semiconductor chip or other component having contacts, hereinafter referred to as generally a microelectronic device.

### SUMMARY OF THE INVENTION

In one embodiment of the present invention, there is described a probe for testing microelectronic devices having a plurality of device contacts thereon, the probe comprising a dielectric substrate having a surface, and a plurality of probe contacts arranged on the surface of the substrate, each of the probe contacts comprising a first probe contact having an exposed surface and at least one second probe contact extending upwardly from the exposed surface of the first probe contact.

In another embodiment of the present invention, there is described a probe for testing microelectronic devices having a plurality of device contacts thereon, the probe comprising a dielectric substrate having a planar surface, and a plurality of probe contacts arranged on the surface of the substrate, each of the probe contacts including a blind opening formed by a bottom wall and at least a partially surrounding lateral wall, wherein each of the probe contacts is adapted to receive one of the device contacting within the opening in contact with at least one of the bottom wall and the lateral wall.

In a further embodiment of the present invention, there is described a microelectronic device test package comprising a microelectronic device having a plurality of device contacts thereon; and a probe comprising a dielectric substrate having a planar surface, a plurality of probe contacts arranged on the surface of the substrate in alignment with the plurality of device contacts, each of the probe contacts including a blind opening formed by a bottom wall and at least a partially surrounding lateral wall, wherein each of the device contacts are received in one of the openings within the probe contacts in engagement with at least one of the bottom wall and the lateral wall.

In another embodiment of the present invention, there is described a method of testing a microelectronic device having a plurality of device contacts thereon using a probe, the method comprising providing a probe having a plurality of probe contacts, each of the probe contacts comprising a first probe contact and at least one second probe contact extending upwardly from the first probe contact, engaging at least one of said plurality of device contacts with one of the plurality of first probe contacts, and engaging at least another one of the device contacts with one of the second probe contacts by displacing the microelectronic device laterally with respect to the probe.

In another embodiment of the present invention, there is described a method of testing a microelectronic device having a plurality of device contacts thereon using a probe, the method comprising providing a probe having a plurality of probe contacts each including a blind opening formed by a bottom wall and at least a partially surrounding lateral wall, and contacting each of the device contacts with one of the bottom wall and the lateral wall by manipulation of the microelectronic device and the probe relative to each other in both vertical and horizontal directions.

### BRIEF DESCRIPTION OF THE DRAWINGS

The subject matter regarded as the invention is particularly pointed out and distinctly claimed in the concluding portion of the specification. The invention, however, both as to organization and method of operation, together with features, objects, and advantages thereof may best be understood by reference to the following detailed description when read with the accompanying drawings in which:

FIG. 1 is a cross-sectional view of a probe for testing microelectronic devices in accordance with an embodiment of the present invention;

FIG. 2 is a top plan view of a probe contact constructed in accordance with an embodiment of the present invention;

FIG. 3 is a top plan view of a probe contact constructed in accordance with an embodiment of the present invention;

FIG. 4 is a top plan view of a probe contact constructed in accordance with an embodiment of the present invention;

FIG. 5 is a top plan view of a probe contact constructed in accordance with an embodiment of the present invention;

FIG. 6 is a cross-sectional view of a portion of a microelectronic device having a plurality of device contacts;

FIG. 7 is an enlarged cross-sectional view of a portion of a microelectronic device contact and probe contact in engagement therewith; and

FIG. 8 is a cross-sectional view showing the assembled relationship of the probe and microelectronic device for testing thereof.

### DETAILED DESCRIPTION

In describing the preferred embodiments of the invention illustrated in the drawings, specific terminology will be used for the sake of clarity. However, the invention is not intended to be limited to the specific terms so selected, and it is to be understood that each specific term includes all technical equivalents that operate in a similar manner to accomplish a similar purpose.

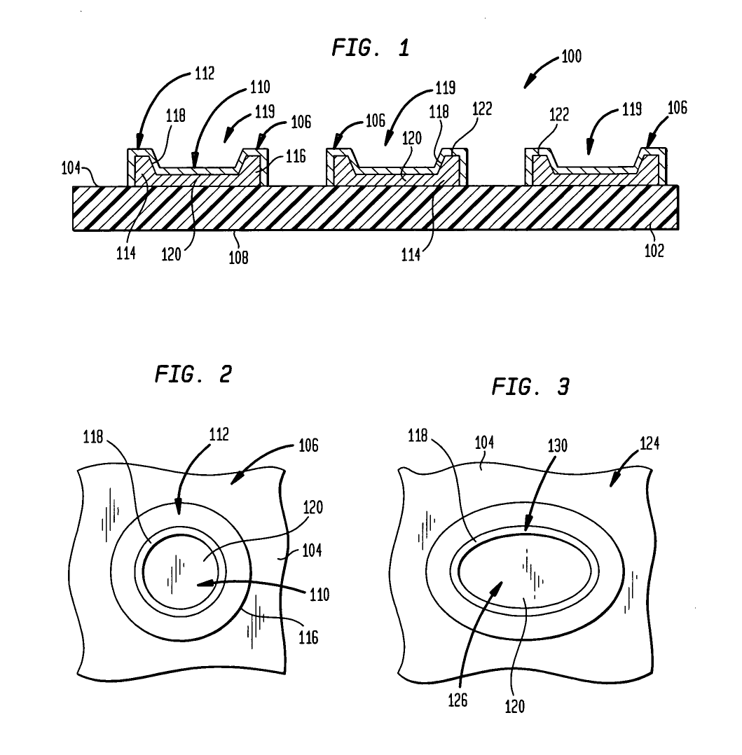

Turning to the drawings, wherein like reference numeral represent like elements, there is shown in FIG. 1 a testing probe constructed in accordance with an embodiment of the present invention generally designated by reference numeral 100. The probe 100 includes a substrate 102 having a planar upper surface 104 supporting a plurality of probe contacts 106 and a bottom surface 108. The substrate 102, in accordance with a preferred embodiment, is formed from a rigid dielectric polymer material such as polyimide. It is to be understood that other polymeric materials may be used for the substrate 102, as well non-polymer materials which have dielectric properties such as ceramic or silicone materials. Although not shown, it is to be understood that the probe 100 will typically include circuitry such as conductive traces which may run along upper surface 104 or bottom surface 108, being interconnected as desired by means of conductive elements are vias extending through the substrate 102. The conductive traces are patterned to provide the desired circuitry for electrical continuity with the plurality of probe contacts 106 as desired for the specific probe 100.

The probe contacts 106 are formed on the substrate 102 which in a preferred embodiment is in a predetermined pattern in accordance with the desired probe circuitry. By way of illustration, the probe contacts 106 may be arranged in a regular matrix array of rows and columns covering a predetermined surface area of the substrate 102. The patterned array of probe contacts 106 will accommodate the location and arrangement of the chip contacts.

With further reference to FIG. 2, there is illustrated an embodiment of a probe contact 106 in accordance with the present invention. Each of the probe contacts include a region defining a first probe contact 110 and another region thereof defining a second probe contact 112. In accordance with the illustrated embodiment, the second probe contact 112 is formed by an endless annular ring structure 114 circumscribing the probe contact 106. The annular ring 114 includes an outer perimeter wall 116 and an inner lateral wall 118. The annular ring 114 provides a blind opening 119 formed by a bottom wall 120 which defines the region of the first probe contact 110 and by the surrounding lateral wall 118. In accordance with the preferred embodiment, the lateral wall 118 is tapered outwardly at a predetermined angle whereby the blind opening 119 has a cross-sectional shape of a truncated cone, for example, from about 45 degrees to about 90 degrees to a vertical axis. As will be more fully described hereinafter, the size of the first probe contact 110 will accommodate receipt and lateral displacement of a chip contact on an opposing microelectronic device during the probing process.

The probe contacts 106 can be formed on the substrate 102 using any known number of processing techniques. For example, the probe contacts 106 can be formed using a suitable additive or subtractive etching process with a photoresist mask and the like. Depending upon the materials of the probe contacts 106, suitable chemical etchants can be used to form the blind opening 119 thereby defining the lateral wall 118 and bottom wall 120 of the first and second probe contacts 110, 112. In addition, it is contemplated that various ablation processes can be used, such as laser ablation to remove material so as to form the probe contacts 106. It will be appreciated that all of the probe contacts 106 will typically be formed simultaneously on the substrate 102. For example, the probe contact material may be deposited as a continuous layer onto the surface 104 of the substrate 102. Using a suitable mask and etching process, the individual probe contacts 106 can be defined. During a first etching process, the shape and arrangement of the probe contacts 106 will be defined. Subsequent photo masking and etching processes will further define the lateral wall 118 and bottom wall 120.

The probe contacts 106 can be formed from a variety of electrically conductive materials. For example, the probe contacts 106 can be formed from copper and copper alloys such as copper-gold or copper-nickel. In accordance with the preferred embodiment, the exposed outer surface of each of the probed contacts 106 is plated with a high conductivity and hardness material. For example, such rugged metals as osmium and rhodium provide the probe contacts 106 with an outer layer 122 of added hardness. The added hardness of the outer layer 122 facilitates the ability of the probe contacts 106 to break through any oxide layer on the engaged microelectronic device contacts to assure reliable electrical connection during the probing process.

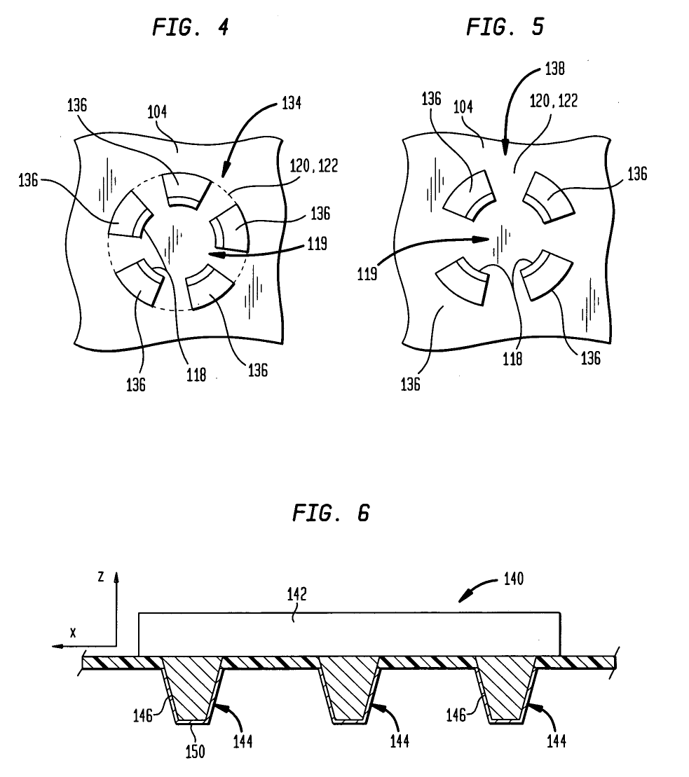

Although the probe contacts 106 have been described as circular, other shapes are contemplated. For example, as shown in FIG. 3, the probe contacts 124 have an oval shape defining an oval shaped first probe contact 126 formed by the bottom wall 120 which is surrounded by an oval shaped continuous upstanding second probe contact 130 having an outwardly tapered lateral wall 118. With reference to FIG. 4, the probe contacts 134 are formed as individual arcuate segments 136 having a lateral wall 118 arranged spaced apart about the circumference of a circle of predetermined size so as to define the blind opening 119 therebetween. The blind opening may be formed by the upper surface 104 of the substrate 102, or by a portion of probe contact 134 being formed by a bottom wall 120 as previously described. Electrical continuity between the segments 136 can be provided by the bottom wall 120 or a conductive outer layer 122 deposited over the upper surface 104 of the substrate 102 between and over the segments 136. Further as shown in FIG. 5, the probe contacts 138 are formed by the segments 136 arranged about an irregularly-shaped opening. The segments 136 are not required to be of equal length nor spaced apart an equal distance. As such, the segments 136 may be arranged in any desired pattern to provide a blind opening 119 therebetween.

An example of a microelectronic device 140 to be tested using the probe 100 in accordance with the present invention is shown in FIG. 6. The microelectronic device 140 is in the nature of a semiconductor chip 142 having a plurality of microelectronic device contacts 144. The device contacts 144 may be formed from a variety of materials, such as copper and copper alloys, in addition to being plated with an outer layer 146 of highly conductivity material having low oxidation properties, such as gold and the like. Although the device contacts 144 are typically immobile in the x and y directions, it is contemplated that the device contacts may be provided with z direction compliancy.

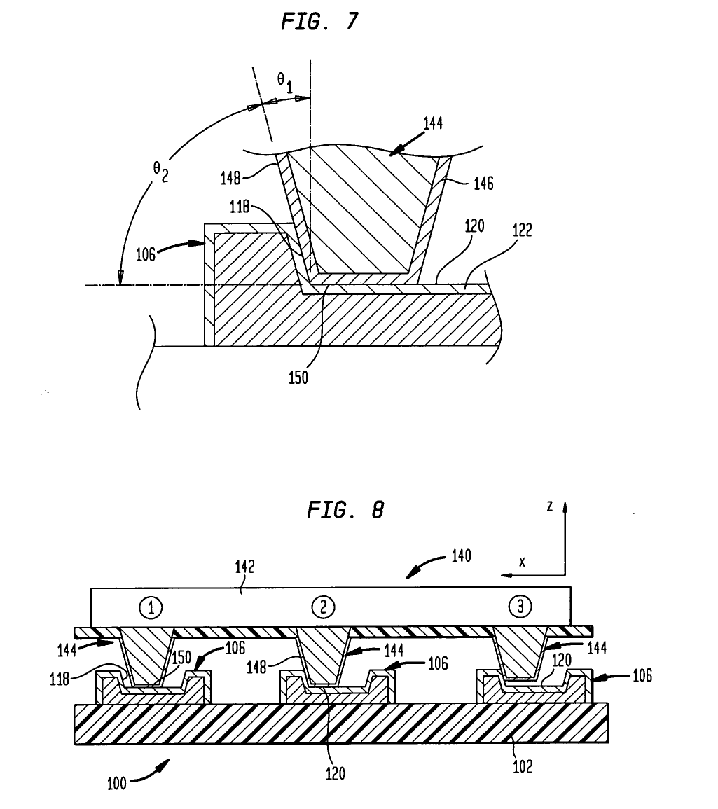

As best shown in FIG. 7, the device contacts 144 in accordance with the preferred embodiment have a truncated cone shape formed by a tapered outer wall 148 arranged at a complimentary angle to the lateral wall 118 of the second probe contact 112 and a planar top wall 150. As a result of the construction of the probe contacts and the device contacts 144, intimate surface contact may be achieved between either or both of (1) the outer wall 148 and lateral wall 118 and (2) bottom wall 120 and top wall 150. Although the device contacts 144 have been described as having a truncated cone shape, complimentary to the blind opening 119 formed by the second probe contacts 112, it is to be understood that other shapes may be employed. For example, the device contacts 144 may have a regular cylindrical shape, a square shape, and the like. Similarly, the blind opening 119 formed by the lateral wall 118 of the second probe contact 112 will typically have a similar shape, for example, a straight lateral wall 118 forming a cylindrical blind opening.

Turning to FIG. 8, there will now be described the probing of a semiconductor chip 142 using the probe 100 of the present invention. The semiconductor chip 142 is juxtaposed overlying the probe 100 with the device contacts 144 aligned with corresponding ones of the probe contacts 106. The semiconductor chip 142 is displaced vertically downward in the z-direction contacting the top wall 150 of the device contacts 144 with the bottom wall 120 of the probe contacts 106 with a predetermined vertical force. While monitoring the contact resistance between the device contacts 144 and the probe contacts 106, the semiconductor chip 142 is displaced horizontally, i.e., laterally, along the x or y directions thereby selectively contacting the outer wall 148 of the device contacts 144 with the lateral wall 118 of the probe contacts 106. The dragging of the semiconductor chip 142 in the horizontal direction under vertical force with respect to the probe contacts 106 is operative for breaking the oxidation layer that may have formed on the outer wall 148 of the device contacts. In addition, the vertical force will displace the device contacts 144 upwardly in the z-direction when the device contacts are formed with z compliancy. In the case of device contacts 144 having higher than average length or height, the vertical force can cause the device contacts to bend thereby enabling adjacent device contact to contact their perspective probe contacts. The contact resistance is further reduced upon contacting the outer wall 148 of the device contacts 144 with the lateral wall 118 of the probe contacts 106.

As thus far described, the probing process is a two-step motion, bringing the semiconductor chip 142 into contact with the probe 100 with a vertical downward motion, and dragging the chip horizontally while applying a vertical force. In addition to the horizontal displacement of the semiconductor chip 142, an arcuate path is contemplated. For example, upon contacting the device contacts 144 with the probe contacts 106, the semiconductor chip 142 can be dragged along a spiral path or other non-linear path so as to engage the second probe contacts 112.

The contact resistance and its variations between the device contacts 144 and probe contact 106 are monitored during their engagement, as low contact resistance with high uniformity is considered an important parameter to achieve reliable test results. The contact resistance value is continuously monitored during the contacting and displacement of the device contacts 144 with the probe contacts 106. The displacement of the semiconductor chip 142 relative to the probe 100 is continued until the overall resistance value being monitored attains a minimum value. At such time, the engaged relationship between the device contacts 144 and probe contacts 106 may be in various configurations such as shown in FIG. 7. Specifically, when in the Number 1 position, the top wall 150 of the device contacts 144 are engaged with the bottom wall 120 of the probe contacts 106 providing z compliancy only. As shown in the Number 2 position, the device contacts 144 and probe contacts 106 provide both z compliance and x compliancy by the outer wall 148 of the device contacts also engaging the lateral wall 118 of the probe contacts. In the Number 3 position, only x compliancy has been attained between the device contacts 144 and the probe contacts 106. Accordingly, low contact resistance is achieved by adding lateral contact to those contacts having poor z-direction contact.

Although the invention herein has been described with reference to particular embodiments, it is to be understood that these embodiments are merely illustrative of the principles and applications of the present invention. It is therefore to be understood that numerous modifications may be made to the illustrative embodiments and that other arrangements may be devised without departing from the spirit and scope of the present invention as defined by the appended claims.

1. A probe for testing microelectronic devices having a plurality of device contacts thereon, said probe comprising:
a dielectric substrate having a surface, and
a plurality of probe contacts arranged on said surface of said substrate, each of said probe contacts comprising a first probe contact having an exposed surface and at least one second probe contact extending upwardly from said exposed surface of said first probe contact.

2. The probe of claim 1, wherein each probe contact includes a plurality of second probe contacts each extending upwardly from said exposed surface of said first probe contact.

3. The probe of claim 1, wherein said second probe contact comprises an endless body extending about the periphery of said probe contact, said endless body having a central opening exposing a portion of said first probe contact.

4. The probe of claim 3, wherein said endless body comprises an annular ring.

5. The probe of claim 3, wherein said opening has a truncated cone shape.

6. The probe of claim 1, wherein said second probe contact includes a lateral portion arranged at a first angle adapted to be engaged by a lateral portion arranged at a second angle of one of said device contacts, said first and second angles comprising complimentary angles.

7. The probe of claim 1, wherein said first angle is from about 45 degrees to about 90 degrees to a vertical axis.

8. The probe of claim 1, wherein said substrate comprises rigid polymer material.

9. The probe of claim 1, wherein said first and second probe contacts are formed from a first electrically conductive material.

10. The probe of claim 9, wherein said first and second probe contacts have an exposed surface, and a second electrically conductive material provided on said exposed surface.

11. A probe for testing microelectronic devices having a plurality of device contacts thereon, said probe comprising:
a dielectric substrate having a planar surface, and
a plurality of probe contacts arranged on said surface of said substrate, each of said probe contacts including a blind opening formed by a bottom wall and at least a partially surrounding lateral wall, wherein each of said probe contacts is adapted to receive one of said device contacts within said opening in contact with at least one of said bottom wall and said lateral wall.

12. The probe of claim 11, wherein said lateral wall comprises a plurality of discontinuous upstanding wall segments.

13. The probe of claim 11, wherein said lateral wall comprises a continuous ring extending about the periphery of said probe contact.

14. The probe of claim 11, wherein said opening is dimensioned whereby a device contact when received therein is capable of being displaced laterally into contact with said lateral wall.

15. The probe of claim 11, wherein said opening has a truncated cone shape.

16. The probe of claim 11, wherein said lateral wall is arranged at an angle of from about 45 degrees to about 90 degrees to a vertical axis.

17. The probe of claim 11, wherein said bottom wall and said lateral wall are formed from a first electrically conductive material.

18. The probe of claim 17, wherein said first electrically material is covered with a second electrically conductive material.

19. A microelectronic device test package comprising:
a microelectronic device having a plurality of device contacts thereon; and
a probe comprising a dielectric substrate having a planar surface, a plurality of probe contacts arranged on said surface of said substrate in alignment with said plurality of device contacts, each of said probe contacts including a blind opening formed by a bottom wall and at least a partially surrounding lateral wall, wherein each of said device contacts are received in one of said openings within said probe contacts in engagement with at least one of said bottom wall and said lateral wall.

20. The package of claim 19, wherein said opening is dimensioned whereby one of said device contacts is displaceable laterally into engagement with said lateral wall.

21. The package of claim 19, wherein said lateral wall comprises a plurality of discontinuous upstanding wall segments.

22. The package of claim 19, wherein said lateral wall comprises a continuous ring extending about the periphery of said probe contact.

23. The package of claim 22, wherein said opening has a truncated cone shape.

24. The package of claim 22, wherein said lateral wall is arranged at an angle of from about 45 degrees to about 90 degrees to a vertical axis.

25. The package of claim 22, wherein said bottom wall and said lateral wall are formed from a first electrically conductive material.

26. The package of claim 22, wherein said first electrically material is covered with a second electrically conductive material.

27. The package of claim 19, wherein said device contacts each include a top wall and a sidewall, wherein a top wall of at least one of said device contacts is in engagement with said bottom wall of one of said probe contacts and wherein a sidewall of at least another one of said device contacts is in engagement with said lateral wall of one of said probe contacts.

28. A method of testing a microelectronic device having a plurality of device contacts thereon using a probe, said method comprising:
providing a probe having a plurality of probe contacts, each of said probe contacts comprising a first probe contact and at least one second probe contact extending upwardly from said first probe contact;
engaging at least one of said plurality of device contacts with one of said plurality of first probe contacts; and
engaging at least another one of said device contacts with one of said second probe contacts by displacing said microelectronic device laterally with respect to said probe.

29. The method of claim 28, wherein said displacing is along a linear path.

30. The method of claim 28, wherein said displacing is along an arcuate path.

31. The method of claim 28, further including monitoring the contact resistance between said device contacts and said probe contacts.

32. The method of claim 31, wherein said displacing step is discontinued when the monitored contact resistance between said device contacts and said probe contacts attains a predetermined resistance.

33. The method of claim 28, wherein said engaging steps comprise manipulation of said microelectronic device and said probe in both vertical and lateral directions relative to each other.

34. The method of claim 28, further including applying a predetermined vertical force when engaging said device contacts with said probe contacts.

35. A method of testing a microelectronic device having a plurality of device contacts thereon using a probe, said method comprising:
providing a probe having a plurality of probe contacts each including a blind opening formed by a bottom wall and at least a partially surrounding lateral wall, and
contacting each of said device contacts with one of said bottom wall and said lateral wall by manipulation of said microelectronic device and said probe relative to each other in both vertical and horizontal directions.

36. The method of claim 35, wherein said horizontal direction is along a linear path.

37. The method of claim 35, wherein said horizontal direction is along an arcuate path.

38. The method of claim 35, further including applying a predetermined vertical force when contacting said device contacts with said probe contacts in said vertical direction.

39. The method of claim 35, further including monitoring the contact resistance between each of said device contacts and said probe contacts.

40. The method of claim 39, wherein said microelectronic device comprises a semiconductor chip.
